(19) United States
(12) Patent Application Publication
(10) Pub. No.: US 2026/0182194 A1
(43) Pub. Date: Jun. 25, 2026

(54) LIGHT EMITTING DISPLAY DEVICE

(71) Applicant: LG Display Co., Ltd., Seoul (KR)

(72) Inventors: Dongil Chu, Gyeonggi-do (KR); JaeWon Lee, Gyeonggi-do (KR); Wonyeol Choi, Gyeonggi-do (KR); MinJoo Kim, Gyeonggi-do (KR)

(21) Appl. No.: 19/396,552

(22) Filed: Nov. 21, 2025

(30) Foreign Application Priority Data
Dec. 19, 2024 (KR) 10-2024-0191033

(51) Int. Cl. H10K 59/35; H10K 59/121; H10K 59/124

(52) U.S. Cl. CPC H10K 59/353; H10K 59/1213; H10K 59/124

(57) ABSTRACT

A light emitting display device include: a substrate, a partially transparent area, and at least one transparent area within the partially transparent area. The substrate includes a display area having a plurality of unit pixels. The partially transparent area is disposed within the display area. The transparent area is disposed between the unit pixels within the partially transparent area. The unit pixel disposed within the partially transparent area includes: a first pixel, a second pixel, and a third pixel arranged next to each other; and a protective pattern around the first pixel, the second pixel, and the third pixel.

### CROSS-REFERENCE TO RELATED APPLICATIONS

Pursuant to 35 U.S.C. § 119(a), this application claims the benefit of an earlier filing date and right of priority to the Korean Patent Application No. 10-2024-0191033 filed on December 19, 2024, the content of which is hereby incorporated by reference in ites entirety.

### TECHNICAL FIELD

The present disclosure relates to a light emitting display device.

### BACKGROUND

Among display devices, the light emitting display device is self-luminous and has a wide viewing angle and an excellent contrast ratio, does not require an additional back light unit, so the light emitting display may be made with light weight and thin thickness, further have the advantage of low power consumption. In particular, among light emitting display devices, organic light emitting display devices may be driven by low voltage direct current (DC) methode, have a fast response speed, and be inexpensive to manufacture.

Particularly, a light emitting display device may have a plurality of pixels, each of pixels including a ligh emitting diode disposed, arrayed in a matrix manner. By placing a transparent area at a predetermined region of the display area, a display device has been developed that may capture or recognize the background scene in the front direction of the display device with an optical device placed at the back of the display device through this transparent area. Such display devices may have a transparent area without light emitting diodes placed in the area where the optical device is placed. To increase transparency of the transparent area, it is necessary to reduce the number of deposited thin layers thereon. For this case, it is required to establish a structure for preventing moisture or oxygen from being penetrated from the exterior environment of the display device.

### SUMMARY

A light emitting display device according to the present disclosure comprises: a substrate, a partial transparent area, a transparent area. The substrate includes a display area having a plurality of unit pixels. The partial transparent area is disposed within the display area. The transparent area is disposed between the unit pixels within the partial transparent area. The unit pixel disposed within the partial transparent area includes: a first pixel, a second pixel, and a third pixel arranged next to each other; and a protective pattern surrounding the first pixel, the second pixel, and the third pixel.

In an example implementation, the unit pixel includes: a first metal layer disposed on the substrate; a buffer layer covering the first metal layer; a semiconductor layer on the buffer layer; a gate insulating layer covering the semiconductor layer; a second metal layer on the gate insulating layer; an intermediate insulating layer covering the second metal layer; a third metal layer on the intermediate insulating layer; a planarization layer covering the third metal layer; a light emitting diode formed on the planarization layer; and an encapsulation layer covering the light emitting diode.

In an example implementation, the protective pattern includes: a first pattern formed in the first metal layer; a second pattern formed in the second metal layer; and a third pattern formed in the third metal layer.

In an example implementation, the first pattern surrounds the unit pixel. The second pattern surrounds the first pattern. The third pattern surrounds the second pattern.

In an example implementation, the protective pattern further includes: a vertical pattern connected to the second pattern through the intermediate insulating layer, the verical pattern surrounding the unit pixel.

In an example implementation, the protective pattern further includes: a vertical pattern connected to the first pattern through the gate insulating layer, the verical pattern surrounding the unit pixel.

In an example implementation, the buffer layer, the intermediate insulating layer and the planarization layer are removed from the transparent area. The transparent area includes: the gate insulating layer on the substrate; a plurality of lens pattern formed by etching some of the gate insulating layer; and the encapsulation layer on the lens pattern.

In an example implementation, the unit pixel includes: a light shielding layer formed in the first metal layer; a gate electrode formed in the second metal layer; and a source electrode connected to one side of the semiconductor layer and a drain electrode connected to another side of the semiconductor layer, the source electrode and the drain electrode formed in the third metal layer. The light emitting diode is connected to the source electrode.

In an example implementation, the light emitting diode includes: an anode electrode; an emission layer on the anode electrode; and a cathode electrode on the emission layer.

In an example implementation, the encapsulation layer includes: a first inorganic layer covering the unit pixel and the transparent area on the light emitting diode; an organic layer on the first inorganic layer; and a second inorganic layer on the organic layer.

In an example implementation, the first pixel is a red pixel. The second pixel is a green pixel. The third pixel is a blue pixel.

In an example implementation, the first pixel, the second pixel and the third pixel are arrayed in a parallel manner next to each other in either a lateral direction or a vertical direction.

In an example implementation, the first pixel and the second pixel are arrayed in a parallel maner next to each other in any one direction of a lateral direction and a vertical direction. The third pixel is arrayed next to any one side of the first pixel and the second pixel.

In an example implementation, the unit pixels arrayed next to the partial transparent area among the plurality of unit pixels include the protective pattern surrounding the first pixel, the second pixel and the third pixel.

In an example implementation, the light emitting display device further comprises: an optical device disposed under the substrate corresponding to the partial transparent area.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is a plan view illustrating a schematic structure of a light emitting display device according to an implementation of the present disclosure.

FIG. 2 is an enlarged plan view illustrating a structure of three pixels sequentially disposed in the light emitting display device according to an implementation of the present disclosure.

FIG. 3 is an enlarged cross-sectional view, along line I-I’ of FIG. 2, illustrating a structure of one pixel disposed in a light emitting display device according to an implementation of the present disclosure.

FIG. 4 is an enlarged plan view illustrating a structure of a partial transparent area where an optical device is disposed in a light emitting display device according to an example of the present disclosure.

FIG. 5 is an enlarged plan view, enlarging rectangular ‘A’ area, illustrating a structure of a partial transparent area of a light emitting displayd device according to a first implementation of the present disclosure.

FIG. 6 is an enlarged cross-sectional view, along line II-II’ of FIG. 5, for illustrating a structure of a partial transparent area at which an optical device is disposed in a light emitting display device according to an implementation of the present disclosure.

FIG. 7 is an enlarged plan view illustrating a structure of a unit pixel disposed in a partial transparent area in a light emitting display device according to a second implementation of the present disclosure.

FIG. 8 is an enlarged plan view illustrating a structure of a unit pixel disposed in a partial transparent area in a light emitting display device according to a third implementation of the present disclosure.

### DETAILED DESCRIPTION

Implementations of the present disclosure can provide a light emitting display device in which a transparent area is arranged in a predetermined region of the display area, and an optical device is arranged on the back surface thereof.

The light emitting display device can have a larger display area by arranging pixels at the transparent area so that an image is displayed even in the area where circuitry for the optical device is placed.

For example, implementations of of the present disclosure can provide a light emitting display device having a structure for inhibiting moisture or oxygen from intruding from the outside of the display device into pixels arranged adjacent to the transparent area.

The light emitting display device according to implementations of the present disclosure may have an advantage of being able to transmit optical information on the front side of the display panel to optical device located on the back side of the display panel by arranging transparent areas next to unit pixels on a portion of the display panel.

For a light emitting display device according to the present disclosure, a transparent area may have a structure in which only the reduced number of transparent thin layers may be deposited and stacked. Therefore, the transparent area may ensure improved transmittance. A protective pattern may be disposed around the pixels adjacent to the transparent area to surround each of the pixels. Even though moistures or foreign materials penetrate from the outside through the transparent area where the reduced number of transparent thin layers are deposited, these moistures or foreign materials may be inhibited from spreading to the adjacent pixels. Accordingly, the transmittance of the transparent area may be ensured while the functions of adjacent pixels may be protected, thereby improving reliability.

The light emitting display device according to the present disclosure may utilize various optical functions, such as a camera function, an infrared detection function, and a facial recognition function, by arranging an optical device on the back surface of the area where the transparent area is placed. By enhancing the light transmittance of the transparent region, the performance of optical functions may be improved. In addition, a protective pattern may be configured in a multi-layered structure around pixels adjacent to the transparent area to protect the function of the pixels and ensure reliability.

In addition to the effects of the present disclosure mentioned above, other features and advantages of the present disclosure are described below, or may be clearly understood by those skilled in the art from such descriptions and explanations.

Advantages and features of the present disclosure, and implementation methods thereof will be clarified through following implementations described with reference to the accompanying drawings. The present disclosure may, however, be embodied in different forms and should not be construed as limited to the implementations set forth herein. Rather, these example implementations are provided so that this disclosure may be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example implementations of the present disclosure, are merely given by way of example. Therefore, the present disclosure is not limited to the illustrated details. Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary implementations of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various implementations of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked”, “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various implementations of the present disclosure may be partially or overall coupled to or combined with each other, and may be variously inter-operated with each other and driven technically as those skilled in the art can sufficiently understand. The implementations of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

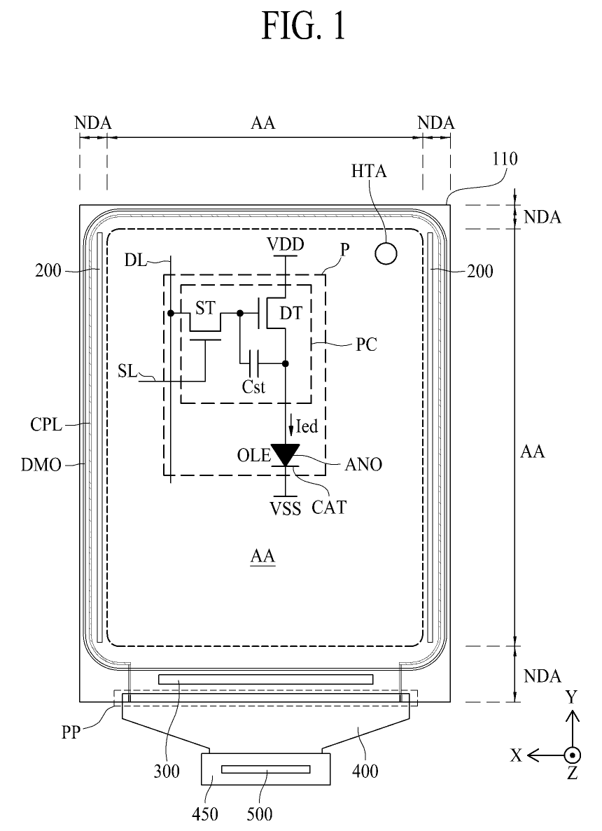

Hereinafter, referring to the attached figures, the present disclosure will be explained. Since a scale of each of elements shown in the accompanying drawings may be different from an actual scale for convenience of description, the present disclosure is not limited to the scale shown in the drawings. FIG. 1 is a plan view illustrating a schematic structure of a light emitting display device according to an implementation of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a pixel P, a gate (or scan) driver 200, a source driving IC (Integrated Circuit) 300, a pad portion PP, a partial transparent area HTA, a common power line CPL, an outer dam DMO, a flexible circuit film 400, a circuit board 450, and a timing controller 500. The structure shown in FIG. 1 is only an example, but it is not limited thereto, other configuration may be implemented.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for representing the video images, may be defined as the majority middle area of the substrate 110, but it is not limited thereto. For an example, the display area AA may have a rectangular shape, a rectangular shape with rounded corners having a predetermined radius of curvature, or a non-rectangular shape with at least six sides.

The non-display area NDA, which is an area not representing the video images, may be defined at the circumference areas of the substrate 110 surrounding all or some of the display area AA. The non-display area NDA may be defined as a circumferential area or a bezel area in which video or picture image is not displayed. In the non-display area NDA, the gate driver 200, the source driving IC 300 and the pad portion 300 may be formed or disposed.

The gate driver 200 may supply the scan (or gate) signals to the scan lines according to the gate control signal received from the timing controller 500. The gate driver 200 may be formed in the non-display area NDA at any one outside of the display area DA on the substrate 110, as a GIP (Gate driver In Panel) type. GIP type means that the gate driver 200 is directly formed on the substrate 110.

The source driving IC 300 may receive the digital video data and the source control signal from the timing controller 500. The source driving IC 300 may convert the digital video data into the analog data voltages according to the source control signal and then supply that to the data lines. In FIG. 1, the source driving IC 300 is made as chips and mounted on the substrate 110. However, it is not limited thereto, the source driving IC 300 may be configured as another type.

The flexible circuit film 400 may include a plurality of link lines connecting the pad portion PP to the circuit board 450. The flexible circuit film 400 may be attached on the pad portion PP using an anisotropic conducting film, so that the pad portion PP may be connected to the link lines of the flexible circuit film 400.

The circuit board 450 may be attached to the flexible circuit film 400. The circuit board 450 may include a plurality of circuits implemented as the driving chips. For example, the circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 300, based on the timing signal. The timing controller 500 may supply the gate control signal to the gate driver 200 and supply the source control signal to the source driving IC 300. Depending on the product types, the timing controller 500 may be integrated with the source driving IC 300 into one driving chip and may be mounted on the substrate 110.

The display area AA may include a plurality of scan lines SL (or gate lines), a plurality of data lines DL, a plurality of pixel driving lines VDD and a plurality of pixel P. In the display area AA, a plurality of pixels P may be arrayed in a matrix manner. Each pixel P may be defined by a scan line SL, a data line DL and a pixel driving line VDD.

The scan lines SL may be extending along a first direction (X-axis direction) and arrayed with a predetermined gap along a second direction (Y-axis direction). The display area AA of the substrate 110 may include a plurality of scan lines SL parallel to the first direction and arrayed with a gap along the second direction. Here, the first direction may be defined as a lateral direction, and the second direction may be defined as a vertical direction of substrate 110.

The data line DL may be extending along the second direction (Y-axis direction) and arrayed with a predetermined gap along the first direction (X-axis). The display area AA of the substrate 110 may include a plurality of data lines DL parallel to the second direction and arrayed with a gap along the first direction.

The pixel driving line VDD may be disposed on the substrate 110 as being parallel to the data line DL. However, it is not limited thereto. For another example, the pixel driving current VDD may be disposed as being parallel to the scan line SL.

For example, the pixels P may be disposed at the display area AA in a stripe manner. Some pixels P may be configured to form one unit pixel. For example, one unit pixel may include a red pixel, a green pixel and a blue pixel. For another example, one unit pixel may further include a white pixel.

For another example, the pixels P may be disposed at the display area AA in a pentile manner. For example, one unit pixel of pentile manner may include one red pixel, two green pixels and one blue pixel to configure octagonal shape in a plan view. In this case, the blue pixel may have the maximum of aperture area (or emission area), and the green pixel may have the minimum of aperture area.

The pixel P may include a driving element PC electrically connected to a scan line SL and a data line crossing each other and a pixel driving line VDD, and a light emitting element OLE electrically connected to the driving element PC.

The driving element PC may control the electric current Ied flowing from the pixel driving line VDD to the common electrode of the light emitting element OLE based on the data voltage supplied from the data line DL in response to the scan signal supplied from the scan line SL.

For example, the driving element PC may include at least two thin film transistors ST and DT, and one capacitor Cst. For example, the driving element PC may include a driving thin film transistor DT supplying a data current Ied to the light emitting diode OLE, a switching thin film transistor ST supplying the data voltage from the data line DL to the driving thin film transistor DT, and a capacitor Cst storing a gate-source voltage of the driving thin film transistor DT.

For another example, the driving element PC may include at least three thin film transistors and at least one capacitance. For example, the driving element PC may include a current supply circuit, a data supply circuit and a compensation circuit depending on the operation (or function) of each of at least three thin film transistors. Here, the current supply circuit may include a driving thin film transistor that supplies data current Ied to the light emitting diode OLE based on a data voltage. The data supply circuit may include at least one switching thin film transistor tha supplies data voltage supplied from a data line DL to the current supply circuit in response to at least one scan signal. The compensation circuit may include at least one compensation thin film transistor that compensates for a change in a characteristic value (threshold voltage and/or mobility) of the driving thin film transistor in response to at least one scan signal.

The light emitting diode OLE may emit light with a brightness (or luminance) corresponding to the data current Ied supplied from the driving element PC. In this case, the data current Ied may flow from the pixel driving line VDD through the driving thin film transistor DT and the light emitting diode OLE to the low-voltage line VSS.

For example, the light emitting diode OLE may include a pixel electrode ANO (or first electrode or anode electrode) electrically connected to the driving element PC, an emission layer disposed on the pixel electrode ANO, and a common electrode (or second electrode or cathode electrode) contact the emission layer. The common electrode CAT may be connected to the low-voltage line VSS. The low-voltage line VSS may be disposed at one side of the unit pixel. The low-voltage line VSS may be connected to the common power line CPL disposed at the non-display area NDA.

The common power line CPL may be disposed at the non-display area NDA of the substrate 110, and connected to the common electrode CAT disposed at the display area AA via the low-voltage line CPL. For example, the common power line CPL may be placed at the non-display area NDA surrounding the display area AA along the left side, the upper side and the right side of the substrate 110, excepting the lower side of the substrate 110. One end of the common power line CPL may be disposed at the one portion of the non-display area NDA, and the other end of the common power line CPL may be disposed at the other portion of the non-display area NDA. The middle portion from one end of the common power line CPL to the other end of the common power line VSS may be disposed at the non-display area NDA as surrounding the display area AA. Therefore, the common power line CPL may have ‘n’(or ∩) shape in which the lower side of the non-display area NDA may be opened and other sides are closed in plan view.

The outer dam DMO may be disposed at the non-display area NDA of the substrate 110 to have a closed curve structure surrounding the display area AA. For example, the outer dam DMO may be placed outside the common power line CPL so as to be located at the outermost part on the substrate 110. The pad portion PP and the source driving IC 300 may be disposed out of the outer dam DMO in the non-display area NDA.

Even though FIG. 1 shows that the outer dam DMO is disposed at outermost location on the substrate 110, it is not limited thereto. For another example, the outer dam DMO may be disposed between the commo power line CPL and the gate driver 200. For another example, the outer dam DMO may be disposed between the display area AA and the gate driver 200.

The light emitting display device according to the present disclosure may further include the partial transparent area HTA. The partial transparent area HTA may be the area for providing external light to the optical device such as camera or optical sensor by passing through the partial transparent area HTA. Therefore, the partial transparent area HTA may include transparent area TA and unit pixels UP. An optical device arranged on the back surface of the light emitting display device may capture a background scene in front of the light emitting display device or may detect an optical signal transmistted from the front direction through the transparent area TA arranged in the partial transparent area HTA.Since video images may be displayed by the unit pixels UP placed in a partial transparent area HTA, the partial transparent area HTA may have the displaying function.

The partial transparent area HTA may be the area that displays the image and allows light to pass through. Compared with the case in which only transparent areas exist for optical devices, the partial transparent area HTA may have both transparency and image displaying function. Therefore, the partial transparent area HTA may increase the area ratio occupied by the display area AA on the light emitting dislay device. Further, when looking at the light emitting display device, the transparent area TA that allows light to pass through may have a structure that makes it difficult to easily recognize the transparent area TA. Accordingly, the function of the optical device may be performed without revealing where the optical device is installed.

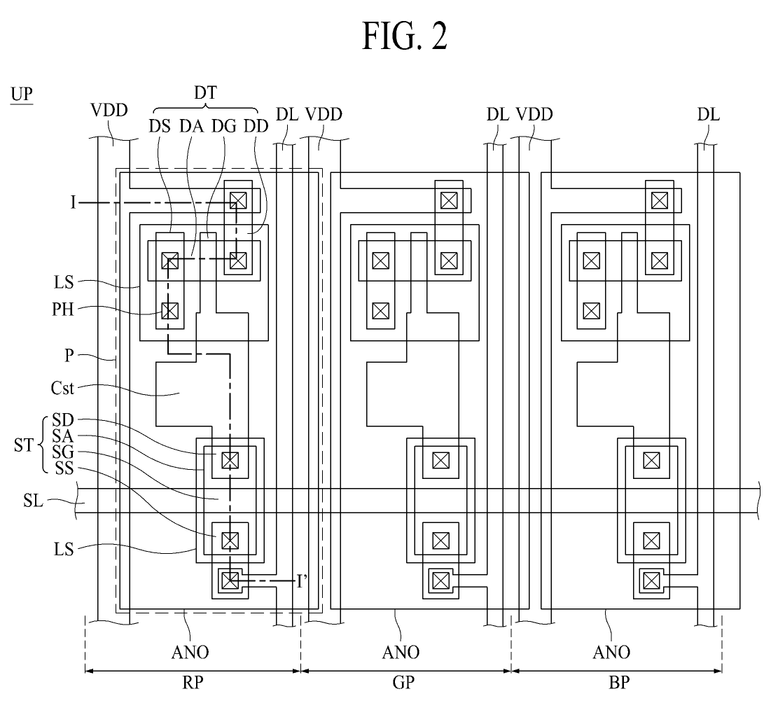

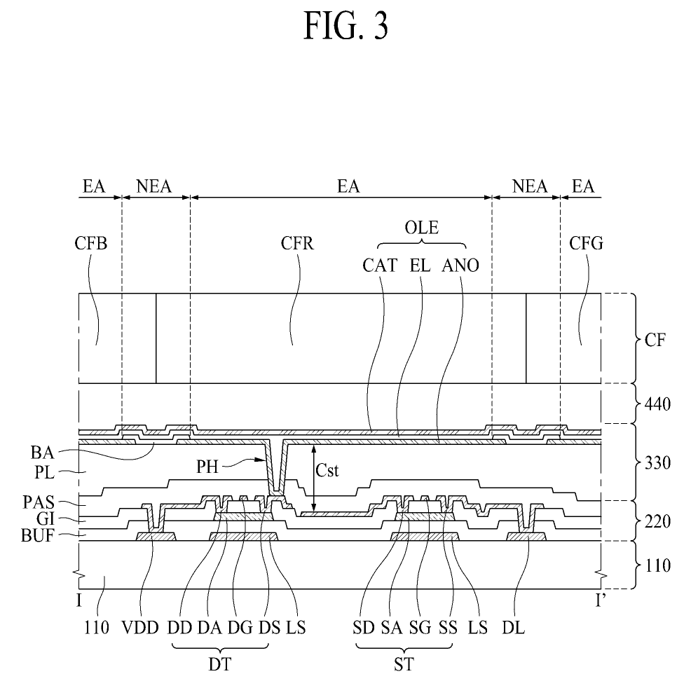

Hereinafter, referring to FIGS. 2 to 3, a structure of a pixel P disposed at the area only having the displaying function in the display area AA of a light emitting display device according to an example of the present disclosure will be explained. FIG. 2 is an enlarged plan view illustrating a structure of three pixels sequentially disposed in the light emitting display device according to an implementation of the present disclosure. FIG. 3 is an enlarged cross-sectional view, along line I-I’ of FIG. 2, illustrating a structure of one pixel disposed in a light emitting display device according to an implementation of the present disclosure.

Each pixel P of the light emitting display according to the present disclosure may be defined by a scan line SL, a data line DL and a driving current line VDD. Each pixel P of the light emitting display may include a switching thin film transistor ST, a driving thin film transistor DT, a light emitting diode OLE and a storage capacitto Cst. The driving current line VDD may be supplied with a high-level voltage for driving the light emitting diode OLE.

A switching thin film transistor ST and a driving thin film transistor DT may be formed on a substrate 110. For example, the switching thin film transistor ST may be configured to be connected to the scan line SL and the data line DL is crossing. The switching thin film transistor ST may include a gate electrode SG, a semiconductor layer SA, a source electrode SS and a drain electrode SD. The gate electrode SG may be a portion of the scan line SL. The semiconductor layer SA may be disposed as crossing over the gate electrode SG. The overlapped portion of the semiconductor layer SA with the gate electrode SG may be defined as the channel area. The source electrode SS may be branched from or connected to the data line DL, and the drain electrode SD may be connected to the driving thin film transistor DT. The source electrode SS may be one side of the semiconductor layer SA from the channel area, and the drain electrode SD may be the other side of the semiconductor layer SA. By supplying the data signal to the driving thin film transistor DT, the switching thin film transistor ST may play a role of selecting a pixel which would be driven.

The driving thin film transistor DT may play a role of driving the light diode OLE of the selected pixel by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be extended from the drain electrode SD of the switching thin film transistor ST. In the driving thin film transistor DT, the drain electrode DD may be branched from or connected to the driving current line VDD, further, the source electrode DS may be connected to the anode electrode (or pixel electrode) ANO of the light emitting diode (or light emitting element) OLE. The semiconductor layer DA may be disposed as crossing over the gate electrode DG. In the semiconductor layer DA, the overlapped portion with the gate electrode DG may be defined as a channel area. The source electrode DS may be connected at one side of the semiconductor layer DA around the channel area, and the drain electrode DD is connected to the other side of the semiconductor layer DA. A storage capacitor Cst may be disposed between the gate electrode DG of the driving thin film transistor DT and the anode electrode ANO of the light emitting diode OLE.

The light emitting diode OLE may generate light according to the current controlled by the driving thin film transistor DT. The driving thin film transistor DT may control the amount of current flowing from the driving current line VDD to the light emitting diode OLE according to the voltage difference between the gate electrode DG and the source electrode DS.

The light emitting diode OLE may include an anode electrode ANO, an emission layer EL, and a cathode electrode CAT. The light emitting diode OLE may emit lights according to the current controlled by the driving thin film transistor DT. In other words, the light emitting diode OLE may provide an image by emitting light according to the current controlled by the driving thin film transistor DT. The anode electrode ANO of the light emitting diode OLE may be connected to the source electrode DS of the driving thin film transistor DT. The cathode electrode CAT (or, common electrode) may be low-power line VSS supplied with the low-potential voltage. Therefore, the light emitting diode OLE may be driven by the electric current flown from the driving current line VDD to the low power line VSS controlled by the driving thin film transistor DT.

A plurality of pixels P may be arrayed on the substrate 110. For example, along the horizontal direction, a red pixel RP, a green pixel GP and a blue pixel BP may be sequentially arrayed and disposed. The combination of the red pixel RP, the green pixel GP and the blue pixel BP may configure one pixel. In another case, the red pixel, the green pixel, the white pixel and the blue pixel may be sequentially arrayed along the horizontal direction. The red pixel, the green pixel, the white pixel and the blue pixel may form a unit pixel. FIG. 2 shows that three pixels P sequentially are arrayed along the horizontal direction.

Referring to FIG. 3, a cross-sectional structure of the light emitting display device according to the present disclosure will be explained. The red pixel RP, the green pixel GP and the blue pixel BP have the same structure, with only the configuration of the color filter layer CF being different. Therefore, the structure of one pixel P may be explained. A light emitting display device may include a substrate 110, a driving element layer 220 and a light emitting element layer 330. The driving element layer 220 and the light emitting element layer 330 may be sequentially stacked on the substrate 110. Further, an encapsulation layer 400 and the color filter layer CF may be sequentially stacked on the light emitting element layer 330.

The driving element layer 220 may include a plurality of thin layers formed on the substrate 110. The driving element layer 220 may include a switching thin film transistor ST and a driving thin film transistor DT. On the substrate 110, a data line DL, a driving current line VDD and a light shielding layer LS may be formed. The light shielding layer LS may be disposed in an island shape spaced apart from the data line DL and the driving current line VDD by a predetermined distance and overlapping the semiconductor layers SA and DA.

A buffer layer BUF is deposited on entire surface of the substrate 110 as covering the data line DL and the driving current line VDD. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other. However, it is not limited thereto, the gate electrode SG and DG may be disposed at the layer different from the source-drain electrode SS-SD and DS-DD. For example, the source-drain electrodes SS-SD and DS-DD may be disposed on an insulating layer covering the gate electrodes SG and DG. The source electrode SS of the switching thin film transistor ST may be connected to the data line DL via a contact hole penetrating the gate insulating layer GI. Further, the drain electrode DD of the driving thin film transistor DT may be connected to the driving current line VDD via another contact hole penetrating the gate insulating layer.

A passivation layer PAS is deposited on the substrate 110 as covering the thin film transistors ST and DT. The passivation layer PAS may be made of an inorganic material such as silicon oxide or silicon nitride.

The light emitting element layer 330 is formed on the driving element layer 220. The light emitting element layer 330 may include a planarization layer PL and a light emitting diode OLE. The surface of the substrate 110 on which the thin film transistors ST and DT are formed is not uniform or even, so the planarization layer PL is a thin film for flattening the uneven surface condition. To make the height difference being even, the planarization layer PL may be formed of an organic material. A pixel contact hole PH exposing a part of the source electrode DS of the driving thin film transistor DT is formed in the passivation layer PAS and the planarization layer PL.

The anode electrode ANO is formed on the top surface of the planarization layer PL. The anode electrode ANO connects to the source electrode DS of the driving thin film transistor DT via the pixel contact hole PH. The anode electrode ANO may have different structure and configuring elements according to the emission type of the light emitting diode OLE. For example, in the case of a bottom emission type that provides lights in the direction of the substrate 110, it may be formed of a transparent conductive material. For another example, in the case of a top emission type that provides lights in the upward direction facing the substrate 110, it may be formed of a metal material having excellent light reflectance. The present disclosure relates to a top emission type light emitting display device, so it is preferable that the anode electrode ANO is made of a metal material.

For example, the anode electrode ANO may include any metal material such as aluminum (Al), magnesium (Mg), calcium (Ca) and silver (Ag), or alloy or metal combination (i.e., aluminum-magnesium (AlMg)). Otherwise, the anode electrode ANO may include a stacked layer such as ITO/Ag/ITO in which indium tin oxide (ITO), one of the transparent conductive materials, and silver are stacked.

A bank BA is formed on the top surface of the substrate 110 having the anode electrode ANO. The bank BA is preferably an insulating layer made of an inorganic material or an organic material. Hereinafter, a case made of an in organic material will be described. The bank BA covers the circumferential areas of the anode electrode ANO, and exposes most of the central area. The central area exposed from the bank BA is defined as an emission area EA, and the area covered by bank BA is defined as a non-emission area NEA.

An emission layer EL is disposed on the anode electrode ANO and bank BA. The emission layer EL may be deposited on entire of the display area AA of the substrate 110 as covering the anode electrode ANO and the bank BA. For an example, the emission layer EL may include at least two emission parts for generating white light. In detail, the emission layer EL may include a first emission part and a second emission part vertically stacked for generating white light by mixing the first light from the first emission part and the second light from the second emission part.

For another example, the emission layer EL may include any one of a blue emission part, a green emission part, and a red emission part for generating light corresponding to a color set in each pixel. Further, the light emitting diode OLE may include a functional layer for improving light emitting efficiency and/or lifetime of the emission layer EL.

A cathode electrode CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT may include a transparent conductive material. For example, the cathode electrode CAT may be made of a transparent conductive material such as indium-tin-oxide (ITO) or indium-zinc-oxide (IZO).

An encapsulation layer 440 is stacked on the light emitting element 220. The encapsulation layer 440 may have a single-layer structure made of an inorganic material, or a multi-layer structure in which several inorganic layers are sequentially stacked. As another example, the encapsulation layer 440 may have a structure in which an inorganic layer, an organic layer and an inorganic layer are continuously stacked. Hereinafter, for convenience of description, the encapsulation layer 440 made of a single inorganic layer will be used for explanation.

A color filter CF is stacked on the encapsulation layer 440. The color filter CF may be disposed in a structure in which one of a red color filter CFR, a green color filter CFG and a blue color filter CFB is assigned to one pixel P. As another example, the color filter CF may be disposed in a structure in which one of a red color filter, a white color filter, a green color filter and a blue color filter is allocated to one pixel P.

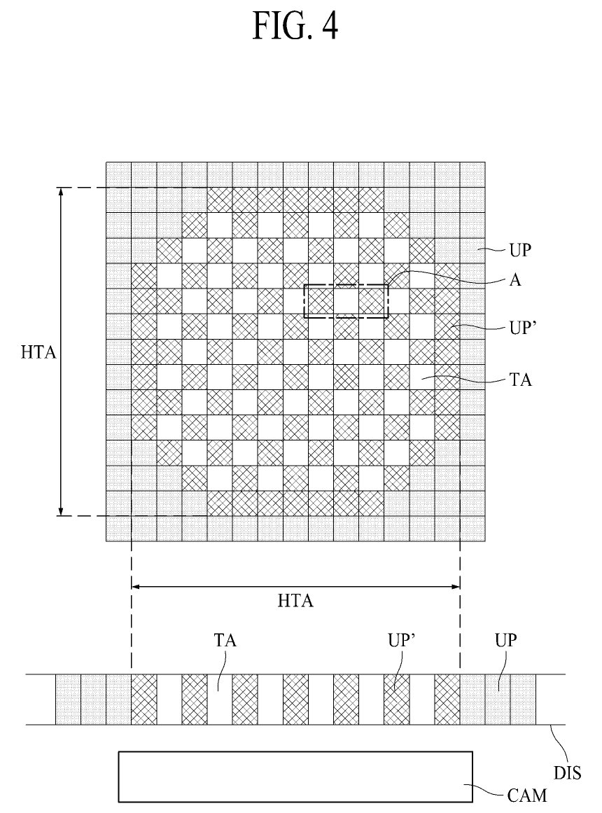

Hereinafter, referring to FIG. 4 a light emitting display device according to an implementation of the present disclosure will be explained. FIG. 4 is an enlarged plan view illustrating a structure of a partial transparent area where an optical device is disposed in a light emitting display device according to an example of the present disclosure.

Referring to FIG. 4, a light emitting display device according to an implementation of the present disclosure may include a display panel DIS and an optical device CAM disposed below the display pandel DIS. The display panel DIS may comprise a display area AA including a plurality of unit pixels UP. The display area AA may also include a partial transparent area HTA. The partial transparent area HTA may include a plurality of transparent area TA and a plurality of adjacent unit pixels UP’. Among the unit pixels UP, the unit pixels located adjacent to the transparent area TA may be called as “adjacent unit pixels UP’.”

The unit pixel UP and the adjacent unit pixel UP’ may have the same size, and may be the elements for providing the image information. The difference is that the adjacent unit pixels UP’ may be further provided with protective patterns LSP, GAP and SDP to prevent the penetration of moisture or oxygen from the outside.

The partial transparent area HTA may have a shape such as circle or ellipse. A plurality of unit pixels UP having rectangular shape may be arrayed in a matrix manner, so the partial transparent area HTA may actually have a polygonal shape rather than a circle or ellips. For example, the partial transparent area HTA may have a octagonal shape. However, it is not limited thereto, the partial transparent area HTA may be in the shape of a 12-gonal shape or 16-gonal shape.

At the border area of the partial transparent area HTA, the adjacent unit pixels UP’ may be arranged to completely surround the partial transparent area HTA. Within the partial transparent area HTA, a plurality of transparent areas TA and a plurality of adjacent unit pixels UP’ are arrayed. In particular, the transparent area TA and the adjacent unit pixel UP’ may be arranged in an alternating manner. For example, the transparent area TA and the adjacent unit pixel UP’ may be alternately arranged one by one along the horizontal direction (X-axis direction) and/or the vertical direction (Y-axis direction).

However, it is not limited thereto. When the size of the partially transparent area HTA may be small and the size of the adjacent unit pixel UP’ may be relatively large, the number of transparent areas TA may be placed more than the number of the adjacent unit pixels UP’ to ensure the transparency performance. For another example of ultra-high resolution display devices with a large partial transparent area HTA and small adjacent unit pixels UP’, the number of adjacent unit pixels UP’ may be placed more than the number of the transparent areas TA.

The transparent area TA may be formed by depositing several transparent thin layers so that lights provided from the front of the display panel may be transmitted and provide to the back surface of the display panel DIS. Meanwhile, in adjacent unit pixels UP’, lights from a light emitting element for displaying image information may be provide in front of the display panel DIS. Therefore, the partial transparent area HTA may be defined as a region that simultaneously performs the dual functions of transmitting light and providing video information.

For example, by placing a camera on the back of the partial transparent area HTA, the image situation in front of the display panel DIS may be captured by the camera. Further, an ultraviolet detector, an infrared detector or a laser receiver may be planced on the back surface of the partial transparent area HTA to receive optical information provided from the front direction of the display panel DIS, so this captured optical information may be used for various purposes.

In order for the optical device positioned on the back of the display panel to accurately receive optical information, it is important for the transparent area TA located in the partial transparent area HTA to ensure as high a transmittance as possible. Therefore, it is required to leave only transparent thin layers with high light-transmittance among the various thin layers that are included in the display device. All of the thin layers that are stacked during forming the the display device may be removed. However, in such cases, the adjacent unit pixel UP’ positioned next to the transparent area TA may be damaged, or moisture or oxygen may penetrate into the adjacent unit pixel UP’, so the adjacent unit pixel UP’ may be inoperable. Therefore, it is preferable to configure the transparent area TA so that as few transparent thin layers as possible are disposed. In particular, it is preferable to configure transparent inorganic thin layers having merits for preventing moisture penetration to cover the transparent area TA.

Further, the adjacent unit pixel UP’ may include the emission layer EL made of organic material. Since the emission layer EL may be vulnerable to moisture, it is preferable to have a structure that prevents moisture from penetrating into the border area of adjacent unit pixels UP’.

In the following implementations, various structures for ensuring transparency and improving optical function may be provide in a transparent area TA.

### <First Implementation>

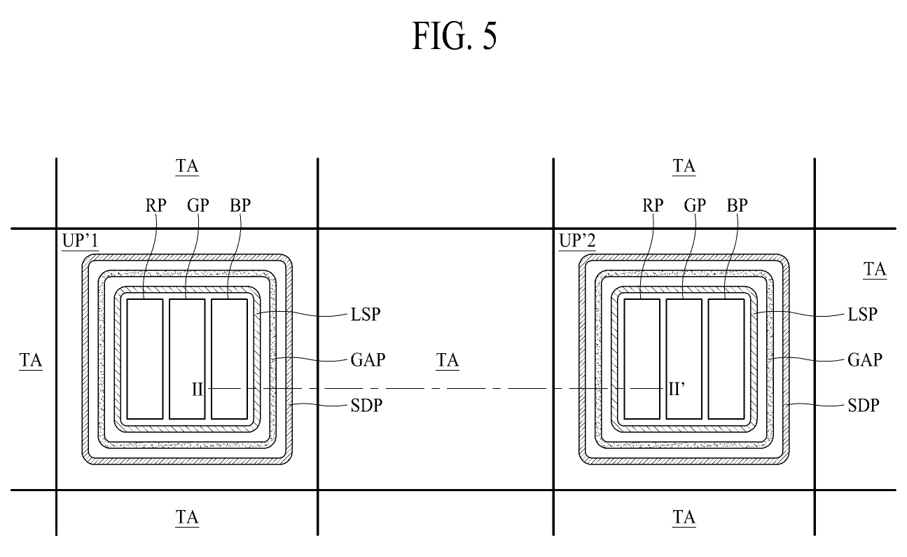

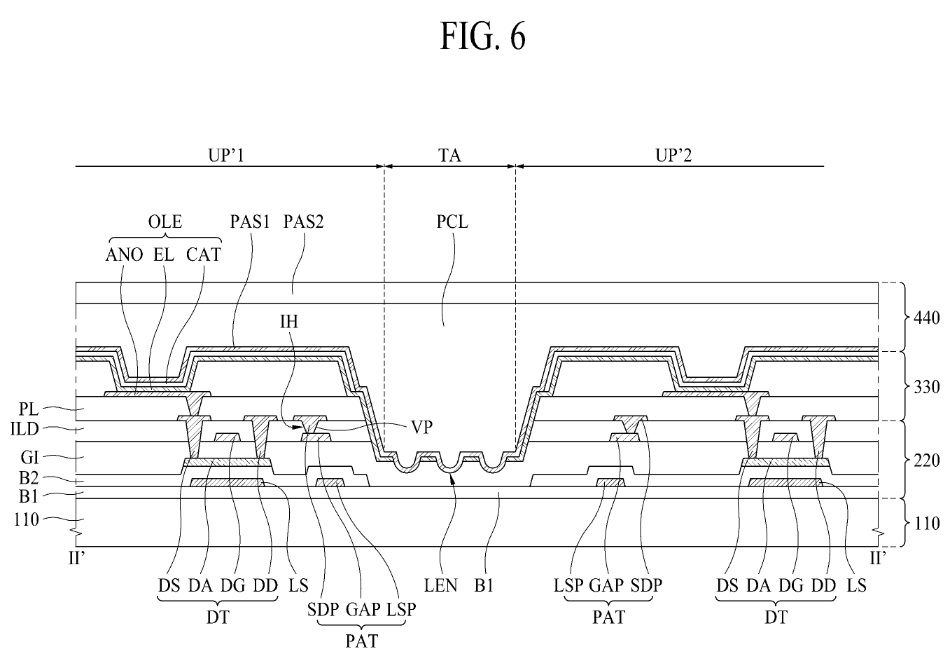

Hereinafter, referring to FIG. 5 and FIG. 6, a structure of a light emitting display device according to a first implementation of the present disclosure will be explained. FIG. 5 is an enlarged plan view, enlarging rectangular ‘A’ area, illustrating a structure of a partial transparent area of a light emitting displayd device according to a first implementation of the present disclosure. FIG. 6 is an enlarged cross-sectional view, along line II-II’ of FIG. 5, for illustrating a structure of a partial transparent area at which an optical device is disposed in a light emitting display device according to an implementation of the present disclosure.

A partial transparent area HTA of a light emitting display device according to a first implementation of the present disclosure may include a plurality of transparent areas TA and a plurality of adjacent unit pixels UP’. The transparent areas TA and the adjacent unit pixels UP’ are alternately arrayed. For example, one adjacent unit pixel UP’ may be placed at each of the upper side, the lower side, the left side and the right side of one transparent area TA. Two transparent areas TA may be arrayed diagonally adjacent to each other. One transparent area TA may be placed at each of the upper side, the lower side, the left side and the right side of one adjacent unit pixel UP’. Two adjacent unit pixels UP’ may be arrayed diagonally adjacent to each other.

For example, a first adjacent unit pixel UP’1, a transparent area TA and a second adjacent unit pixel UP’2 may be sequentially arrayed along lateral direction (X-axis direction). Each of the first adjacent unit pixel UP’1 and the second adjacent unit pixel UP’2 may include a red pixel RP, a green pixel GP and a blue pixel BP. The red pixel RP, the green pixel GP and the blue pixel BP may have a rectangular shape of which vertical (Y-axis) side is longer than the lateral side. The red pixel RP, the green pixel GP and the blue pixel BP may be sequentially arrayed along lateral direction. Each of the first adjacent unit pixel UP’1 and the second adjacent unit pixel UP’2 may include a protective pattern PAT surrounding outer portion of the red pixel RP, the green pixel GP and the blue pixel BP.

The protective pattern PAT may have a closed curve shape completely surrounding the red pixel RP, the green pixel GP and the blue pixel BP. The protective pattern PAT may include a plurality of patterns. For example, the protective pattern may include a first protective pattern LSP (or “a first pattern LSP” for short), a second protective pattern GAP (or “a second pattern GAP” for short), and a third protective pattern LSP (or “a third pattern SDP” for short). The first pattern LSP may be placed closest to the red pixel RP, the green pixel GP and the blue pixel BP and being apart from these pixels with a predetermined distance. The second pattern GAP may have a closed curve shape surrounding the first pattern LSP and being apart from the first pattern LSP. The third pattern SDP may have a closed curve shape surrounding the second pattern GAP and being apart from the second pattern GAP.

Hereiafter, referring to FIG. 6, the cross-sectional structure of the partial transparent area HTA will be explained. The partial transparent area HTA may include a first adjacent unit pixel UP’1, a transparent area TA and a second adjacent unit pixel UP’2. Each of the first adjacent unit pixel UP’1 and the second adjacent unit pixel UP’2 may include a red pixel RP, a green pixel GP and a blue pixel BP. For convenience of explanation, in FIG. 6, only one pixel included in each of the first adjacent unit pixel UP’1 and the second adjacent unit pixel UP’2 is illustrated, further one pixel is illustrated as having only a light emitting diode OLE and a driving thin film transistor DT.

A driving element layer 220, a light emitting element layer 330 and an encapsulation layer 440 may be sequentially stacked on a substrate 110. These layers may have the same structure as explained with FIG. 3, so the same description may not be duplicated.

A first buffer layer B1 may be deposited on the substrate 110. A light shielding layer LS and a first pattern LSP may be formed on the first buffer layer B1. The first pattern LSP may be separated from the light shielding layer LS and may have a closed curve shape surrounding the first adjacent unit pixel UP’1. In some case, the first buffer layer B1 may be omitted.

A second buffer layer B2 may be deposited on the light shielding layer LS and the first pattern LSP. The second buffer layer B2 may be disposed on the adjacent unit pixels UP’1 and UP’2, excepting the transparent area TA. To do so, the structure is configured such that the reduced number of thin layers may be deposited to increase the light transmittance of the transparent area TA.

A semiconductor layer DA may be formed on the second buffer layer B2. The semiconductor layer DA may be overlapped with the light shielding layer LS. The second buffer layer B2 may be disposed to be extended over the transparent area TA. The second buffer layer B2 may include a plurality of lenses LEN at the transparent area TA. For example, a plurality of concave patterns being depressed or sunken some thickness of the second buffer layer B2 into a hemispherical shape may be formed by patterning the second buffer layer B2. For another example, a plurality of convex patterns being extruded or protruded some thickness of the second buffer layer B2 to have a hemispherical shape may be formed by patterning the second buffer layer B2.

However, it is not limited thereto. The first buffer layer B1 may be disposed at the transparent area TA, but the second buffer layer B2 may be removed from the transparent area TA. In this case, by patterning the first buffer layer B1, the plurality of lenses LEN may be formed. For another example, the first buffer layer B1 and the second buffer layer B2 may be disposed at the transparent area TA. In this case, at least one of the first buffer layer B1 and the second buffer layer B2 or both ofh them may have the plurality of lenses LEN. For still another example, the first buffer layer B1 may be disposed at the transparent area TA, but the second buffer layer B2 may be removed from the transparent area TA. In this case, by echting a part of the gate insulating layer GI, the plurality of lenses LEN may be formed.

A gate insulating layer GI may be deposited on the entire surface of the substrate 110 having the semiconductor layer DA. Here, the gate insulating layer GI may be patterned not to be disposed at the transparent area TA.

A gate electrode DG and a second pattern GAP may be formed on the gate insulating layer GI. The gate electrode DG may be disposed as overlapping the central portion of the semiconductor layer DA. The second pattern GAP may be separated from the gate electrode DG, physically and electrically. The second pattern GAP may have a closed curve shape surrounding the first adjacent unit pixel UP’1 or the second adjacent unit pixel UP’2 including the driving thin film transistors DT.

An intermediate insulating layer ILD may be deposited on the gate electrode DG and the second pattern GAP. The intermediate insulating layer ILD may be patterned not to be disposed at the transparent area TA.

A source electrode DS, a drain electrode DD and a third pattern SDP may be formed on the intermediate insulating layer ILD. According to the first implementation shown in FIG. 6, the source electrode DS and the drain electrode DD may be disposed on a different layer from the gate electrode DG. However, it is not limited theretor. As shown in FIG. 3, the source electrode DS and the drain electrode DD amy be disposed at the same layer with the gate electrode DG. The source electrode DS may contact one side of the semiconductor layer DA. The drain electrode DD may contact another side of the semiconductor layer DA. The third pattern SDP may be separated from the source electrode DS and the drain electrode DD, physically and electrically. The third pattern SDP may have a closed curve shape surrounding the first adjacent unit pixel UP’1 or the second adjacent unit pixel UP’2 including the driving thin film transistors DT.

FIG. 6 shows that the protective pattern PAT including the first pattern LSP, the second pattern GAP and the third pattern SDP may be located only at the right side of the first adjacent unit pixel UP’1. However, the protective pattern PAT may be surrounding the first adjacent unit pixel UP’1. Similarly, the protective pattern PAT may be arranged to surround the second adjacent unit pixel UP’2.

A planarization layer PL may be deposited on the entire surface of the substrate 110 having the source electrode DS, the drain electrode DD and the third pattern SDP. The planarization layer PL may be patterned not to be disposed at the transparent area TA.

An anode electrode ANO may be formed on the planarization layer PL. The anode electrode ANO may be connected to the source electrode DS. A bank BA may be formed on the anode electrode ANO. The bank may cover the circumferential area of the anode electrode ANO and expose the middle portion of the anode electrode ANO to define an emission area. The bank BA may be patterned not to be disposed at the transparent area TA.

The light transmittance may be improved by not depositing the intermediate insulating layer ILD, the planarization layer PL and the bank BA in the transparent area TA. Even though the intermediate insulating layer ILD, the planarization layer PL and the bank BA may be formed of the transparent materials, by removing them so that they are not placed in the transparent area TA, the light transmittance may be further improved.

An emission layer EL may be deposited on entire surface of the substrate 110 having the bank BA and the anode electrode ANO. As the transparent area TA may not have the intermediate insulating layer ILS, the planarization layer PL and the bank BA, the emission layer EL may be in surface contact with the second buffer layer B2, in the transparent area TA. With this condition, by patterning the emission layer EL and the second buffer layer B2, a plurality of lenses LEN may be formed. As a result, the emission layer EL may be removed at the lens LEN part, but the emission layer EL may be remained between the lenses LEN as a dummy emission layer.

A cathode electrode CAT may be deposited on the emission layer EL. It is preferable that the cathode electrode CAT may be formed as a single layer connected over the entire surface of the substrate 110. It is preferable to configure the cathode electrode CAT so as to connect not only all adjacent unit pixels UP’ but also the unit pixels UP. Therefore, it is preferable that the cathode electrode CAT may be also deposited in a transparent area TA located between adjacent unit pixels UP’. The light emitting display device according to the present disclosure relates to a top emission type light emitting display device, so it is preferable for the cathode electrode CAT to be made of a transparent conductive material. Therefore, enven though the cathode electrode CAT is deposited in the transparent area TA, the light transmittance of the transparent area TA may not be degraded.

An encapsulation layer 440 may be disposed on the cathode electrode CAT. The encapsulation layer 440 may be an element that prevents foreign materials from penetrating from the outside, and protects the light emittind diode OLE and the elements deposited thereunder. Therefore, it is preferable to apply the encapsulation layer 440 over the entire surface area of the substrate 110. For example, it is preferable that the encapsulation layer 440 may be placed not only in the adjacent unit pixel UP’ but also in the transparent area TA.

To prevent foreign materials from penetrating from the outside and to protect the elements, an encapsulating layer 440 should be disposed on the transparent area TA. Even though the encapsulation layer 440 may be made of the transparent materials, when too many thin layers are deposited on the transparent area TA, the light transmittance may be reduced. In the light emitting display device according to the first implementation, the bank BA, the planarization layer PL, the intermediate insulating layer ILD and the second buffer layer B2 may be removed from the transparent area TA. Accordingly, light transmittance may be ensured by stacking a reduced number of thin layers in the transparent area TA. In some cases, the first buffer layer B1 may also be removed from the transparent area TA to further ensure the transmittance of the transparent area TA.

Due to the thin layers removed to improve light transmittance in the transparent area TA, the transparent area TA may be vulnerable to prevent penetration of foreign materials from the outside or to prevent diffusion of moisture. Considering the path through which moisture may penetrate from the outside, the moisture may penetrate through the etched side of the patterned planarization layer PL and the intermediate insulating layer ILD so as to be removed from the transparent area TA. Further, moisture may penetrate through the upper surface of the gate insulating layer GI patterned to form the lenses LEN.

The light emitting display device according to the first implementation may include the protective pattern PAT for preventing moisture from penetrating and for preventing the moisture penetrated into the transparent area TA from spreading in the direction of the light emitting diode OLE. The protective pattern PAT may be formed to surround the adjacent unit pixel UP’.

The protective pattern PAT may include a first pattern LSP formed in the same layer with the light shielding layer LS, a second pattern GAP formed in the same layer with the gate electrode DG, and a third pattern SDP formed in the same layer with the source-drain electrode DS-DD.

In particular, the protective pattern PAT may further include a vertical pattern VP linking the second pattern SDP to the second pattern GAP. The vertical pattern VP may be formed by patterning the intermediate insulating layer ILD to expose upper surface of the second pattern GAP and then forming the third pattern SDP thereon. Here, it is preferable that the contact hole IH formed in the intermediate insulating layer ILD exposing the upper surface of second pattern GAP may bave a closed curve shape surrounding the adjacent unit pixel UP’ the same with the second pattern GAP. Similarly, it is preferable that the vertical pattern VP may have a closed curve shape surrounding the adjacent unit pixel UP’ in the same manner as the third pattern SDP.

The second pattern GAP may further include a vertical pattern connecting with the first pattern LSP physically. In this case, the vertical pattern formed in the second pattern GAP may have a closed curve shape surrounding the adjacent unit pixel UP’.

The first pattern LSP, the second pattern GAP and the third pattern SDP may be disposed as overlapping each other in the cross-sectional view. However, they may be arranged at a certain distance from each other, such as in a concentric circle structure. In FIG. 5, the first pattern LSP is located at the innermost position, the third pattern SDP is located at the outermost position, and the second pattern GAP is located at middle position, e.g., between the first pattern LSP and the third pattern SDP. However, it is not limited thereto. The first pattern LSP may be disposed at the outermost position, or middle position. On the other hand, the second pattern GAP may be located at the outermost position, or at the innermost position.

The light emitting display device according to the first implementation may increase light transmittance by reducing the number of thin layers in the partial transparent area HTA and improve light receiving efficiency by forming lens LEN. Further, by forming a protective pattern PAT to surround the adjacent unit pixels UP’ positioned next to the transparent area TA, the penetration and diffusion of foreign materials and moisture from the outside may be prevented.

### <Second Implementation>

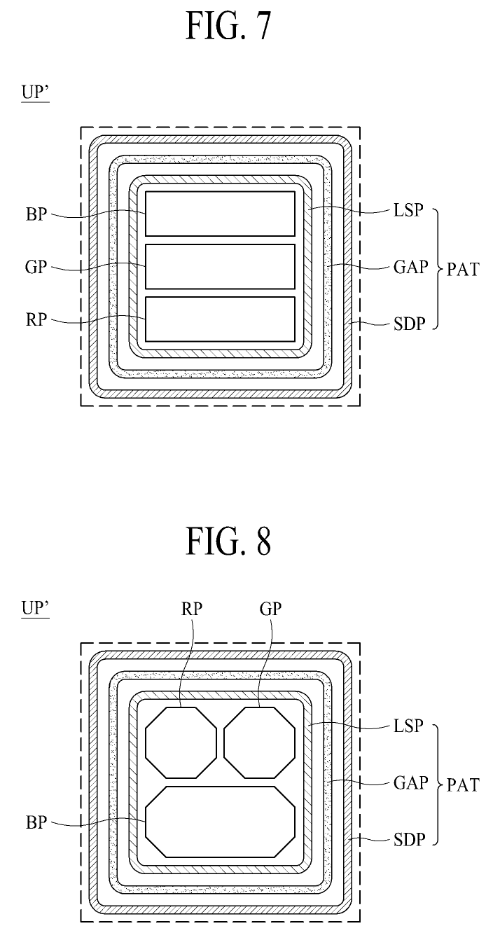

Hereinafter, referring to FIG. 7, a light emitting display device according to a second implementation of the present disclosure will be explained. FIG. 7 is an enlarged plan view illustrating a structure of a unit pixel disposed in a partial transparent area in a light emitting display device according to a second implementation of the present disclosure.

Referring to FIG. 7, the adjacent unit pixel UP’ may include a red pixel RP, a green pixel GP and a blue pixel BP. In particular, each of the red pixel RP, the green pixel GP and the blue pixel BP may have a rectangular shape in which lateral length (X-axis length) is longer than the vertical length (Y-axis length). The red pixel RP, the green pixel GP and the blue pixel BP may be arrayed vertically next to each other. However, it is not limited thereto, the adjacent unit pixel may further include a white pixel. The white pixel may be disposed between the red pixel RP, the green pixel GP and the blue pixel BP.

The adjacent unit pixel UP’ may include a protective pattern PAT. The protective pattern PAT may have a closed curve shape surrounding the red pixel RP, the green pixel GP and the blue pixel BP. The protective pattern PAT may include at least two patterns. For example, the protective pattern PAT may include a first pattern LSP, a second pattern GAP, and a third pattern SDP. However, it is not limited thereto, one or two of the first pattern LSP, the second pattern GAP, and the third pattern SDP may be omitted. For another example, the protective pattern PAT may further include a fourth pattern. In this case, the fourth pattern may be disposed between the first pattern LSP, the second pattern GAP, and the third pattern SDP. For another example, the fourth pattern may be disposed innermost position. For another example, the fourth pattern may be disposed at outside of the third pattern SDP.

The light emitting display device according to the second implementation may include a partial transparent area HTA in the display area AA like the first implementation. The partial transparent area HTA may include an adjacent unit pixel UP’ and a transparent area TA. The cross-sectional structure of the adjacent unit pixel UP’ and the transparent area TA according to the second implementation may be same as the first implementation, so the duplicated explanations are not duplicated. The light emitting display device according to the second implementation may have increased light transmittance by reducing the number of thin layers in a partial transparent are HTA, and improved light receiving efficiency by forming lenses LEN. Further, by forming the protective pattern PAT surrounding the adjacent unit pixel UP’ disposed near to the transparent area TA, the light emitting display device according to the second implementation may prevent the penetration and spread of foreign materials and moisture from outside.

### <Third Implementation>

Hereinafter, referring to FIG. 7, a light emitting display device according to a third implementation of the present disclosure will be explained. FIG. 8 is an enlarged plan view illustrating a structure of a unit pixel disposed in a partial transparent area in a light emitting display device according to a third implementation of the present disclosure.

Referring to FIG. 8, an adjacent unit pixel UP’ may include a red pixel RP, a green pixel GP and a blue pixel BP. In particular, the area ratio of the red pixel RP, the green pixel GP and the blue pixel BP may be different each other. For example, the red pixel and the green pixel may have the same area ratio, but the blue pixel may have an area ratio twice that of the red pixel RP. In detail, the red pixel RP and the green pixel GP may have a square shape and are arranged laterally next to each other. The blue pixel BP may be arrayed next to the lower sides of the red pixel RP and the green pixel GP. The blue pixel BP may have an area corresponding to the sum of the areas of the red pixel RP and the green pixel GP.

For another example, the red pixel RP and the green pixel GP may have square shapes, and may be arranged vertically next to each other. The blue pixel BP may be arrayed next to the right side or the left side of the red pixel RP and the green pixel GP. The blue pixel BP may have an area corresponding to the sum of the areas of the red pixel RP and the green pixel GP.

The arrangement of the pixels disposed in one adjacent unit pixel UP’ shown in FIG. 8 may have a structure that may be applied when the light efficiency of the blue pixel BP is low. It is not limited thereto, when the light efficiency of the red pixel RP is required to be higher than other pixels, the array structure may be changed so that the area ratio of the red pixel RP is larger than those of other pixels.

For another example, the adjacent unit pixel UP’ may further include a white pixel. In this case, the red pixel, the white pixel, the green pixel and the blue pixel may have the same size and arrayed in 2X2 matrix manner.

The adjacent unit pixel UP’ may include a protective pattern PAT. The protective pattern PAT may have a closed curve shape surrounding the red pixel RP, the green pixel GP and the blue pixel BP. The protective pattern PAT may include at least two patterns. For example, the protective pattern PAT may include a first pattern LSP, a second pattern GAP, and a third pattern SDP. However, it is not limited thereto, one or two of the first pattern LSP, the second pattern GAP, and the third pattern SDP may be omitted. For another example, the protective pattern PAT may further include a fourth pattern. In this case, the fourth pattern may be disposed between the first pattern LSP, the second pattern GAP, and the third pattern SDP. For another example, the fourth pattern may be disposed innermost position. For another example, the fourth pattern may be disposed at outside of the third pattern SDP.

The light emitting display device according to the third implementation may include a partial transparent area HTA in the display area AA like the first implementation. The partial transparent area HTA may include an adjacent unit pixel UP’ and a transparent area TA. The cross-sectional structure of the adjacent unit pixel UP’ and the transparent area TA according to the third implementation may be same as the first implementation, so the duplicated explanations are not duplicated. The light emitting display device according to the third implementation may have increased light transmittance by reducing the number of thin layers in a partial transparent are HTA, and improved light receiving efficiency by forming lenses LEN. Further, by forming the protective pattern PAT surrounding the adjacent unit pixel UP’ disposed near to the transparent area TA, the light emitting display device according to the third implementation may prevent the penetration and spread of foreign materials and moisture from outside.

The features, structures, effects and so on described in the above example implementations of the present disclosure are included in at least one example implementation of the present disclosure, and are not necessarily limited to only one example implementation. Furthermore, the features, structures, effects and the like explained in at least one example implementation may be implemented in combination or modification with respect to other example implementations by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that implementations of the present disclosure cover the various substitutions, modifications, and variations of the present disclosure, provided they come within the scope of the appended claims and their equivalents. These and other changes can be made to the implementations in light of the above detailed description. In general, in the following claims, the terms used should not be construed to limit the claims to the specific example implementations disclosed in the specification and the claims, but should be construed to include all possible implementations along with the full scope of equivalents to which such claims are entitled. Accordingly, the claims are not limited by the disclosure.

What is claimed is:

1. A light emitting display device comprising:
a substrate including a display area having a plurality of unit pixels; and
a partially transparent area disposed within the display area, wherein the partially transparent area comprises at least one transparent area and at least one unit pixel;
wherein each transparent area is disposed between unit pixels among the at least one unit pixel within the partially transparent area,
wherein a unit pixel among the at least one unit pixel disposed within the partially transparent area includes:
a first pixel, a second pixel, and a third pixel arranged next to one another; and
a protective pattern around the first pixel, the second pixel, and the third pixel.

2. The light emitting display device according to claim 1, wherein the unit pixel disposed within the partially transparent area includes:
a first metal layer disposed on the substrate;
a buffer layer covering the first metal layer;
a semiconductor layer on the buffer layer;
a gate insulating layer covering the semiconductor layer;
a second metal layer on the gate insulating layer;
an intermediate insulating layer covering the second metal layer;
a third metal layer on the intermediate insulating layer;
a planarization layer covering the third metal layer;
a light emitting diode formed on the planarization layer; and
an encapsulation layer covering the light emitting diode.

3. The light emitting display device according to claim 2, wherein the protective pattern includes:
a first pattern formed in the first metal layer;
a second pattern formed in the second metal layer; and
a third pattern formed in the third metal layer.

4. The light emitting display device according to claim 3, wherein the first pattern surrounds the unit pixel,
wherein the second pattern surrounds the first pattern, and
wherein the third pattern surrounds the second pattern.

5. The light emitting display device according to claim 3, wherein the protective pattern further includes:
a vertical pattern connected to the second pattern through the intermediate insulating layer, the verical pattern surrounding the unit pixel.

6. The light emitting display device according to claim 3, wherein the protective pattern further includes:
a vertical pattern connected to the first pattern through the gate insulating layer, the verical pattern surrounding the unit pixel.

7. The light emitting display device according to claim 2, wherein the buffer layer, the intermediate insulating layer and the planarization layer are removed from the transparent area,
wherein the transparent area includes:
the gate insulating layer on the substrate;
a plurality of lens pattern formed by etching a part of the gate insulating layer; and
the encapsulation layer on the lens pattern.

8. The light emitting display device according to claim 2, wherein the unit pixel disposed within the partially transparent area further includes:
a light shielding layer formed in the first metal layer;
a gate electrode formed in the second metal layer; and
a source electrode connected to one side of the semiconductor layer and a drain electrode connected to another side of the semiconductor layer, the source electrode and the drain electrode formed in the third metal layer,
wherein the light emitting diode is connected to the source electrode.

9. The light emitting display device according to claim 2, wherein the light emitting diode includes:
an anode electrode;
an emission layer on the anode electrode; and
a cathode electrode on the emission layer.

10. The light emitting display device according to claim 2, wherein the encapsulation layer includes:
a first inorganic layer covering the light emitting diode in the unit pixel and further disposed in the transparent area;
an organic layer on the first inorganic layer; and
a second inorganic layer on the organic layer.

11. The light emitting display device according to claim 1, wherein the first pixel is a red pixel,
wherein the second pixel is a green pixel, and
wherein the third pixel is a blue pixel.

12. The light emitting display device according to claim 1, wherein the first pixel, the second pixel, and the third pixel are arrayed in a parallel manner next to one another in either a lateral direction or a vertical direction.

13. The light emitting display device according to claim 1, wherein the first pixel and the second pixel are arrayed in a parallel maner next to each other in any one direction of a lateral direction and a vertical direction, and
wherein the third pixel is arrayed next to any one side of the first pixel and the second pixel.

14. The light emitting display device according to claim 1, wherein the unit pixels arrayed next to the transparent area among the plurality of unit pixels include the protective pattern surrounding the first pixel, the second pixel and the third pixel.

15. The light emitting display device according to claim 1, further comprising:
an optical device disposed under the substrate corresponding to the partially transparent area.
